(19) United States
(12) Patent Application Publication
(10) Pub. No.: US 2013/0050914 A1
(43) Pub. Date: Feb. 28, 2013

(54) COVER AND PORTABLE ELECTRONIC DEVICE USING SAME

(71) Applicants: ZHENG SHI, Shenzhen City (CN); JIANG-FENG LIU, Shenzhen City (CN)

(72) Inventors: ZHENG SHI, Shenzhen City (CN); JIANG-FENG LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/279,954

(22) Filed: Oct. 24, 2011

(30) Foreign Application Priority Data
Aug. 30, 2011 (CN) 201110252841.8

(51) Int. Cl. H05K 5/03; B29C 45/00; B32B 3/30

(52) U.S. Cl. 361/679.01; 428/167; 264/328.1

(57) ABSTRACT

A cover is made of transparent or semi-opaque material by injection molding. The cover includes a first surface and a second surface opposite to the first surface. The first surface defines a grating surface. The invention further provides a portable electronic device using the cover.

### CROSS-REFERENCE TO RELATED APPLICATIONS

The present application is related to one co-pending U.S. Patent Application (Attorney Docket No. US41580), each entitled “COVER ASSEMBLY AND PORTABLE ELECTRONIC DEVICE USING SAME”, by Shi et al. These applications have the same assignee as the present application and have been concurrently filed herewith. The above-identified applications are incorporated herein by reference.

### BACKGROUND

1. Technical Field

The disclosure generally relates to a cover and a portable electronic device using the same.

2. Description of the Related Art

Portable electronic devices (e.g. mobile phones) may include a cover and a decorative diffractive grating attached on surfaces of the cover. Typically, the grating may be adhered to the cover, but is often not stable enough and may easily become detached from the cover.

Therefore, there is room for improvement within the art.

### BRIEF DESCRIPTION OF THE DRAWINGS

Many aspects of the exemplary cover and portable electronic device using same can be better understood with reference to the following drawings. The components in the various drawings are not necessarily drawn to scale, the emphasis instead being placed upon clearly illustrating the principles of the exemplary cover and portable electronic device using same. Moreover, in the drawings, like reference numerals designate corresponding parts throughout the diagrams.

FIG. 1 is an assembled view of an exemplary portable electronic device.

FIG. 2 is a cross-sectional view of the portable electronic device shown in FIG. 1 along the line II-II.

FIG. 3 is a schematic cross-sectional view of an injecting mold for manufacturing the portable electronic device shown in FIG. 1.

### DETAILED DESCRIPTION

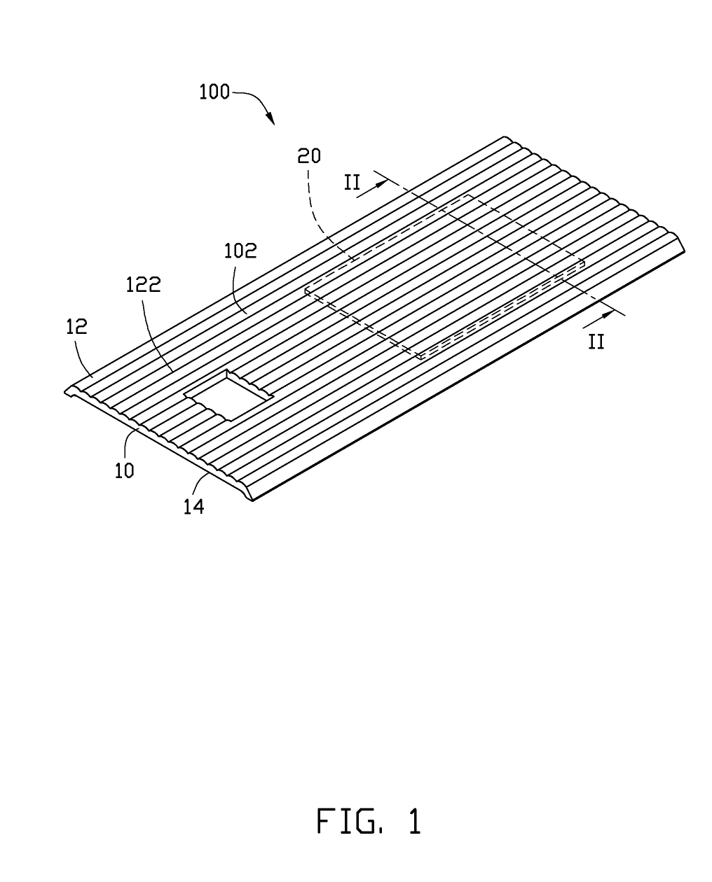

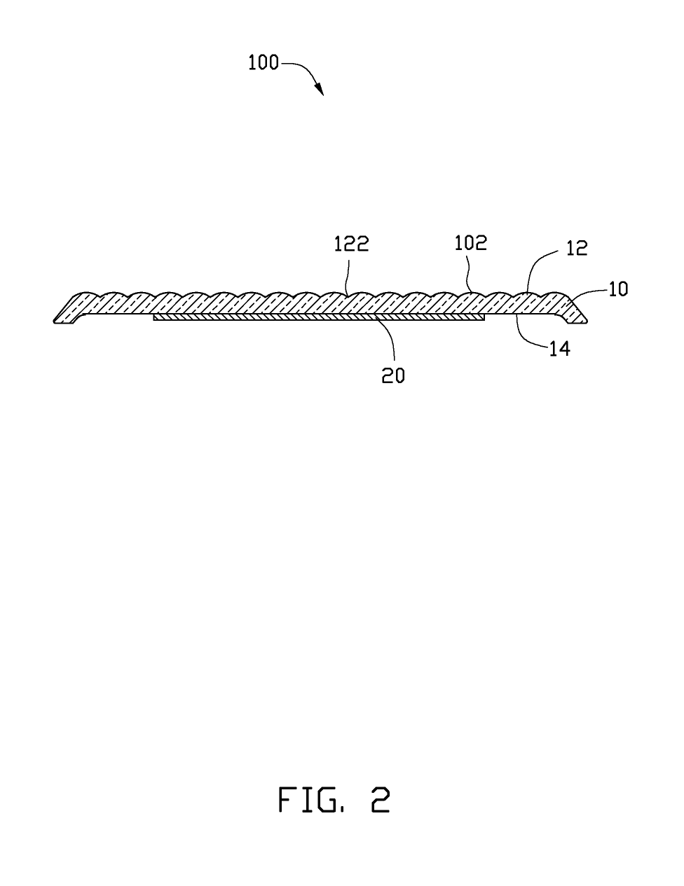

FIGS. 1 and 2 show an exemplary portable electronic device 100 (e. g. mobile phone). The portable electronic device 100 includes a cover 10 and a pattern section 20. The cover 10 includes a first surface 12 and a second surface 14 opposite to the first surface 12. The first surface 12 defines a grating surface 102. The grating surface 102 is formed by defining a plurality of parallel grooves in the first surface 12. The pattern section 20 is adhered on the second surface 14.

The cover 10 may be made of transparent or semi-opaque thermosetting material, such as one selected from a group of polycarbonate, polymethyl methacrylate, acrylonitrile butadiene styrene, and polystyrene.

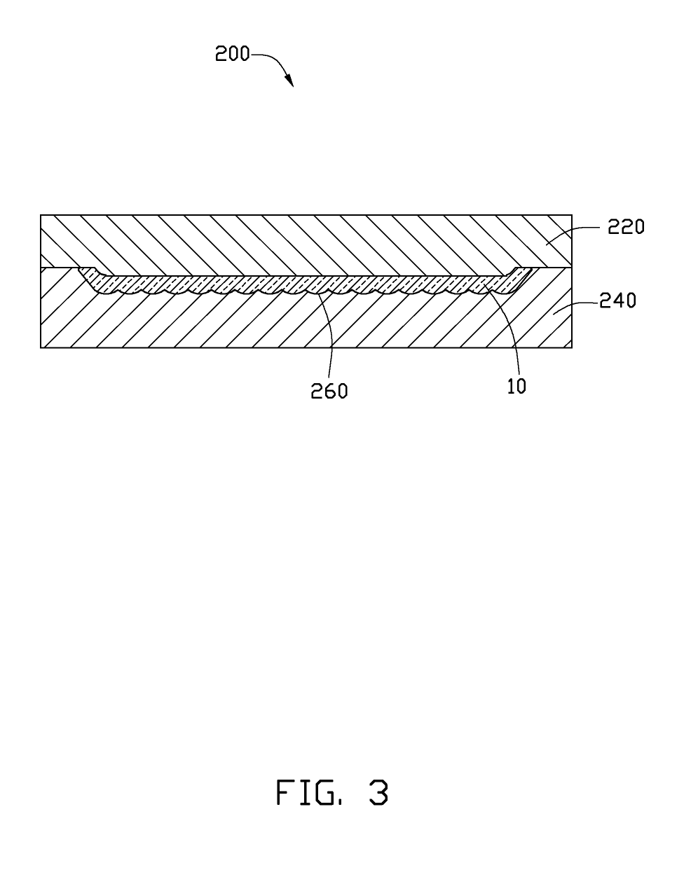

Referring to the FIG. 3, a method of manufacturing the cover 10 may include following steps:

An injecting mold 200 is provided. The injecting mold 200 includes a male mold portion 220 and a female mold portion 240, both of which cooperatively define a mold cavity 260 for molding the cover 10.

The mold 200 is closed and liquid thermosetting or semi-opaque material is injected into the first cavity 260. The liquid thermosetting or semi-opaque material may be one selected from a group of polyethylene, polyvinyl alcohol, polypropylene, polycarbonate, polymethyl methacrylate, acrylonitrile butadiene styrene, and polystyrene. The cover 10 is molded by cooling and opening the mold 200.

The pattern section 20 is printed on the second surface 14.

In use of the portable electronic device 100, the 3D effect of the pattern section 20 may be observed when light is shone through the grating surface 102.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A cover made of transparent or semi-opaque material by injection molding comprising:
a first surface defining a grating surface; and
a second surface opposite to the first surface.

2. The cover as claimed in claim 1, wherein the cover further comprises a pattern section adhered on the second surface.

3. The cover as claimed in claim 1, wherein the grating surface is formed by defining a plurality of parallel grooves in the first surface.

4. The cover as claimed in claim 1, wherein the transparent or semi-opaque material is one selected from a group of polyethylene, polyvinyl alcohol, polypropylene, polycarbonate, polymethyl methacrylate, acrylonitrile butadiene styrene, and polystyrene.

5. The cover as claimed in claim 4, wherein the transparent or semi-opaque material is polymethyl methacrylate.

6. A portable electronic device comprises:
a cover made of transparent or semi-opaque material by injection molding comprising:
a first surface defined a grating surface; and
a second surface opposite to the first surface.

7. The portable electronic device as claimed in claim 6, wherein the cover further comprises a pattern section adhered on the second surface.

8. The portable electronic device as claimed in claim 6, wherein the grating surface is formed by defining a plurality of parallel grooves in the first surface.

9. The portable electronic device as claimed in claim 6, wherein the transparent or semi-opaque material is one selected from a group of polyethylene, polyvinyl alcohol, polypropylene, polycarbonate, polymethyl methacrylate, acrylonitrile butadiene styrene, and polystyrene.

10. The portable electronic device as claimed in claim 9, wherein the transparent or semi-opaque material is polymethyl methacrylate.
